(19) United States
(12) Patent Application Publication
(10) Pub. No.: US 2024/0237318 A9
(43) Pub. Date: Jul. 11, 2024

(54) Configurable Faraday Cage

(71) Applicant: Ajay Subramaniam Krishnan, Los Altos, CA (US)

(72) Inventor: Ajay Subramaniam Krishnan, Los Altos, CA (US)

(21) Appl. No.: 18/492,687

(22) Filed: Oct. 23, 2023

Related U.S. Application Data
(60) Provisional application No. 63/418,610, filed on Oct. 23, 2022.

(51) Int. Cl. H05K 9/00; H10N 70/20

(52) U.S. Cl. CPC H05K 9/0071; H10N 70/20; H10N 70/231; G02F 1/0327; H05K 9/0081

(57) ABSTRACT

A configurable cage of Faraday has a cavity enveloped by a layer of conductive material whose resistance can be modified by an external stimulus. The conductive material may be inside or outside a substrate or may be without a substrate. The layer may be continuous, or applied in a pattern, such as a mesh. The conductive material can be a perovskite or a phase-change memory material, and the external stimulus can be electrical. Various electrical pulses can be used to configure the resistance/conductivity of the material, and therefore the level of shielding from magnetic waves that the Faraday cage provides.

### REFERENCES

This application claims priority from U.S. provisional patent application serial no. 63/418,610, entitled “Design and Construction of a Configurable Faraday Cage”, filed on Oct. 23, 2022. The priority application is hereby incorporated by reference, as if it is set forth in full in this specification.

This application refers to work described in “Faraday-like Screening by Two-Dimensional Nanomaterials: A Scale-Dependent Tunable Effect” by Alberto Ambrosetti and Pier Luigi Silvestrelli, J. Phys. Chem. Lett. 2019, 10, 9, 2044-2050, Apr. 9, 2019, https://doi.org/10.1021/acs.jpclett.9b00860, American Chemical Society.

Each publication, patent, and/or patent application mentioned in this specification is herein incorporated by reference in its entirety to the same extent as if each individual publication and/or patent application was specifically and individually indicated to be incorporated by reference.

### BACKGROUND

### Technical Field

The disclosed technology is generally in the field of shielding against electromagnetic fields, and more particularly in the field of Faraday cages.

### Context

A Faraday Cage is an enclosure that is used to shield electro-magnetic radiation. The cage includes conducting material which by conducting current protects people and equipment inside. Faraday cages are used in a variety of applications including shields for electronic equipment, protective suits for electricians, protection against electro-magnetic signal interference, and prevention of electronic eavesdropping.

The subject matter discussed in this section should not be assumed to be prior art merely as a result of its mention in this section. Similarly, a problem mentioned in this section or associated with the subject matter provided as background should not be assumed to have been previously recognized in the prior art. The subject matter in this section merely represents different approaches, which in and of themselves can also correspond to implementations of the claimed technology.

### BRIEF DESCRIPTION OF THE DRAWINGS

The technology will be described with reference to the drawings, in which:

FIG. 1 illustrates a conventional Faraday cage.

FIG. 2 illustrates a sectional view of a configurable Faraday cage that has a perovskite film on a substrate, in an implementation of the technology disclosed herein.

FIG. 3 illustrates an example of a perovskite film between two conducting electrodes.

FIG. 4 illustrates an example of a perovskite film between two electrodes in an electrical circuit with a voltage applied.

FIG. 5 illustrates an example of a single electrical pulse that may be applied to a perovskite film in an implementation of the technology.

FIG. 6 shows an example I-V graph of a sample film before and after being subject to a +2V pulse.

FIG. 7 illustrates an example of a single electrical pulse of a larger amplitude compared to FIG. 6.

FIG. 8 illustrates an example of a single electrical pulse of different pulse width.

FIG. 9 illustrates an example of multiple electrical pulses that may be applied to the conductive film.

FIG. 10 illustrates an example of a single negative electrical pulse that may be applied to a conductive film to reverse the shielding effect.

FIG. 11 illustrates an example of a single negative electrical pulse of larger amplitude compared to FIG. 10.

FIG. 12 illustrates an example of multiple negative electrical pulses that may be applied to a conductive film to reverse the shielding effect.

FIG. 13 illustrates an example of applying repeated positive and negative electrical pulses to obtain a repeated resistance change.

FIG. 14 illustrates an example of a perovskite film between a first electrode and a second electrode, exposed to hydrogen.

In the figures, like reference numbers may indicate functionally similar elements. The systems and methods illustrated in the figures—and described in the Detailed Description below—may be arranged and designed in a wide variety of different implementations. Neither the figures nor the Detailed Description are intended to limit the scope as claimed. Instead, they merely represent examples of different implementations.

### DETAILED DESCRIPTION

A Faraday cage is an enclosure that is used to shield an object from electromagnetic radiation. The object can be inside the cage when the source of the electromagnetic radiation is outside, or vice versa. The cage comprises a cavity enveloped by a layer of conductive material. The conductive material conducts currents and effectively short-circuits electromagnetic fields to protect people, equipment, or anything else that needs protection. The short-circuit prevents the flow of radiation in either direction through the surface. Faraday cages are used in a variety of applications including shields for electronic equipment, protective suits for electricians, protection against electromagnetic signal interference, and prevention of electronic eavesdropping. Since conventional Faraday cages are made using permanently conducting materials such as metals, their behavior is fixed and does not change.

This document describes a configurable Faraday cage that can be used to partially or fully enforce the Faraday shielding effect. In this technology, the layer of conductive material is made of a material whose electrical resistance can be modified by an external stimulus. Several such materials exist, and the conductive layer may include, for example, a perovskite, a metal oxide, an oxide of metallic alloys, or a phase-change memory (PCM) material.

Several types of external stimulus exist, and an implementation may use, for example, an electric or magnetic field, a chemical, hydrogen, an electrolyte, a solid, a liquid, a gas, an operating temperature, an ambient temperature, or a pressure.

For some of the materials, the modified resistance (and electromagnetic shielding) continues as long as the external stimulus is applied. For other materials, the modified resistance and electromagnetic shielding continue after the external stimulus has been applied, and a different external stimulus may reverse the effect.

### Terminology

As used herein, the phrase one of should be interpreted to mean exactly one of the listed items. For example, the phrase one of A, B, and C should be interpreted to mean any of: only A, only B, or only C.

As used herein, the phrases at least one of and one or more of should be interpreted to mean one or more items. For example, the phrase at least one of A, B, and C or the phrase at least one of A, B, or C should be interpreted to mean any combination of A, B, and/or C.

Unless otherwise specified, the use of ordinal adjectives first, second, third, etc., to describe an object, merely refers to different instances or classes of the object and does not imply any ranking or sequence.

The term coupled is used in an operational sense and is not limited to a direct or an indirect coupling. Coupled to is generally used in the sense of directly coupled, whereas coupled with is generally used in the sense of directly or indirectly coupled. Coupled in an electronic system may refer to a configuration that allows a flow of information, signals, data, or physical quantities such as electrons between two elements coupled to or coupled with each other. In some cases the flow may be unidirectional, in other cases the flow may be bidirectional or multidirectional. Coupling may be galvanic (in this context meaning that a direct electrical connection exists), capacitive, inductive, electromagnetic, optical, or through any other process allowed by physics.

The term connected is used to indicate a direct connection, such as electrical, optical, electromagnetic, or mechanical, between the things that are connected, without any intervening things or devices.

The term configured to perform a task or tasks is a broad recitation of structure generally meaning having circuitry that performs the task or tasks during operation. As such, the described item can be configured to perform the task even when the unit/circuit/component is not currently on or active. In general, the circuitry that forms the structure corresponding to configured to may include hardware circuits, and may further be controlled by switches, fuses, bond wires, metal masks, firmware, and/or software. Similarly, various items may be described as performing a task or tasks, for convenience in the description. Such descriptions should be interpreted as including the phrase configured to.

As used herein, the term based on is used to describe one or more factors that affect a determination. This term does not foreclose the possibility that additional factors may affect the determination. That is, a determination may be solely based on specified factors or based on the specified factors as well as other, unspecified factors. Consider the phrase determine A based on B. This phrase specifies that B is a factor that is used to determine A or that affects the determination of A. This phrase does not foreclose that the determination of A may also be based on some other factor, such as C. This phrase is also intended to cover an implementation in which A is determined based solely on B. The phrase based on is thus synonymous with the phrase based at least in part on.

The terms substantially, close, approximately, near, and about refer to being within minus or plus 10% of an indicated value, unless explicitly specified otherwise.

The following terms or acronyms used herein are defined at least in part as follows:

A perovskite is any material with a crystal structure following the formula ABX₃, which was first discovered as the mineral called perovskite, and which consists of calcium titanium oxide (CaTiO3). Examples of perovskite are strontium titanate, calcium titanate, lead titanate, bismuth ferrite, lanthanum ytterbium oxide, silicate perovskite, lanthanum manganite, yttrium aluminum perovskite (YAP), lutetium aluminum perovskite (LuAP), and perovskite nickelate (NNO).

A phase-change memory (PCM) material is a material that can change between an amorphous and a crystallized state, for example as a result of heat stimulation, and whose electrical resistance is different in the crystallized state than in the amorphous state. Several such materials are used and researched for use in non-volatile memories, but they can also be used for constructing a configurable cage of Faraday. Example materials are chalcogenide materials, compounds based on sulfur, selenium, or tellurium, such as GeSe, AsS, GeAsTe, GeSbTe (GST), and Ge₂Sb₂Te₅.

### Implementations

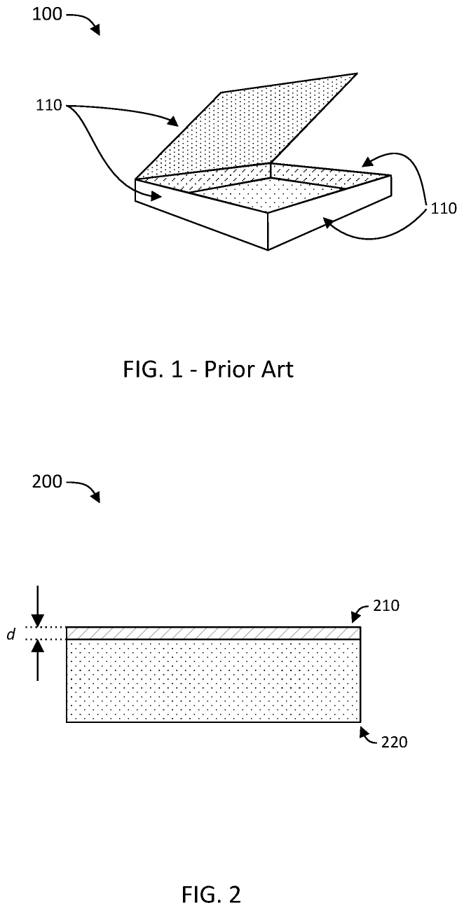

FIG. 1 illustrates a conventional Faraday cage 100. Faraday cage 100 includes a container with conducting surfaces 110. The container may have the shape of a box, as drawn, or any other shape. As drawn, the container has a lid that may be opened to place an object to be shielded from electromagnetic fields; closed to apply the shielding; and reopened to take out the object when shielding is no longer needed. In some cases, the conducting surfaces is without a supporting structure. Examples of such implementations are a metal box, and a cage. In other implementations, the conducting surface is outside or inside a supporting structure, or a substrate. For example, a wooden box may be covered with a metal film on its inside or its outside.

The conducting surfaces may include continuous surfaces (such as a continuous film). Alternatively, the conducting surfaces may include a patterned structure such as a mesh (like in a cage structure). Sometimes, the conducting surfaces include a conductive film or conductive layer that has one or more openings smaller than the wavelength of the electromagnetic field to be protected against. For example, a microwave oven with a window protects against radiation from inside its Faraday cage with a mesh applied to the window. Holes in the mesh are smaller than the (˜12 cm) wavelength of the 2.45 GHz electromagnetic field. Thus, shielding may be selective, and frequency dependent.

In an implementation of the disclosed technology, the conductive material has an electrical resistance that can be modified by an external stimulus, and the layer of conductive material is configured to receive the external stimulus. The cage may have any shape. The layer of conductive material may be attached to a substrate, or it may be self-supporting. The layer of conductive material may be in a continuous film, or it may be applied at least partially in a pattern, such as a mesh or a stripe. The conductive material can be any material whose electrical resistance changes in response to an external stimulus, for example it can include a perovskite, a metal oxide, an oxide of metallic alloys, and/or a phase-change memory material. The conductive material may be doped with a chemical to increase a speed of a resistance change. The external stimulus may be, or include, an electrical stimulus such as a voltage or a current, a chemical, hydrogen, an electrolyte, a solid, a liquid, a gas, an operating temperature, an ambient temperature, or a pressure. In some materials (and implementations), the change in electrical resistance (or conductivity) lasts as long as the external stimulus is applied. In other materials (and implementations), the change in electrical resistance (or conductivity) remains after the external stimulus has been applied, and a different external stimulus may need to be applied to reverse the change. Thus, an implementation can have selective shielding (i.e., frequency-dependent shielding) against electromagnetic radiation, and configurable shielding, that may provide any level of shielding from no shielding to full shielding.

In some implementations, the cage may be operated at room temperature. In other implementations, the cage may be operated at a temperature higher than room temperature. The temperature may directly change the material's resistance, as well as indirectly through increased oxygenation. The speed and range of configuration can be changed with the operating temperature. An increase in temperature may be accomplished using a heating element.

In some implementations, the cage may be operated at standard atmospheric pressure. In other implementations, the cage may be operated at a pressure different from standard atmospheric pressure. The operating pressure may, for example, impact the resistance through the level of oxygenation.

FIG. 2 illustrates a sectional view 200 of a configurable Faraday cage that has a perovskite film 210 on a substrate 220, in an implementation of the technology disclosed herein. In general, a configurable Faraday cage has a cavity, or inside, which is enveloped by a layer of conductive material whose resistance can be modified by an external stimulus. The layer of conductive material is configured to receive the external stimulus. The choice of the material of conductive material depends on the choice of substrate, or vice versa. Substrates may be electrically insulating. For example, the substrate may be made of glass. The Perovskite film 210 material may be chosen to match the lattice parameters of the substrate. In one implementation, the perovskite is perovskite nickelate NdNiO3 (NNO). In another implementation, the perovskite is a germanium antimony tellurium (GST) alloy. In yet another implementation, it may be any other perovskite. The film thickness may be varied to control the effectiveness of the shielding and the speed of the transition from a conducting to an insulating state and vice-versa. The thickness (d) of the film may vary from sub-nm to several cm, for example from one-tenth of a nanometer (0.1 nm) to three centimeters (3 cm).

The conductive material may be deposited on the surface of the substrate through various techniques, including sputtering, pulsed layer deposition (PLD) and Atomic Layer Deposition (ALD). Some manufacturing processes may require an anneal, for instance to ensure that the oxide has reached the Perovskite phase. The Perovskite phase can be confirmed using X-Ray Diffraction (XRD) analysis.

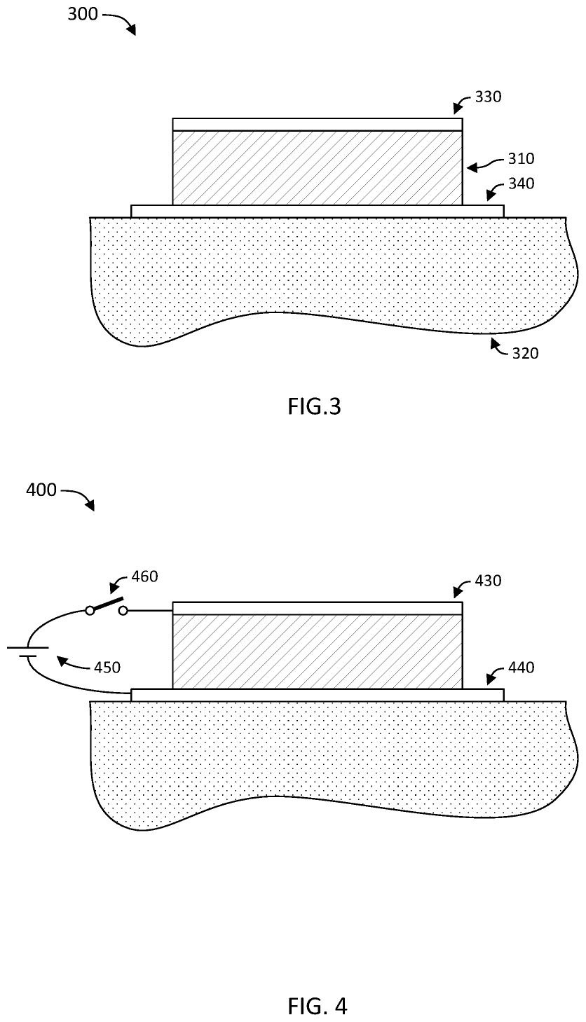

FIG. 3 illustrates an example sectional view 300 of a perovskite film between two conducting electrodes. The perovskite film 310 is placed between a first electrode 330 and a second electrode 340, which may be used for applying an external electrical stimulus, such as a voltage or a current. For example, the external stimulus may be one or more electrical pulses, of which the amplitude may be between minus ten volts (−10 V) and plus ten volts (+10 V). It is possible to have intermediate levels of shielding using electrical pulses of a lower voltage or a higher voltage. The sandwich structure may be placed on substrate 320. In some implementations, the conducting electrodes may be metallic. In some implementations, these electrodes may include, but are not limited to platinum, palladium and gold.

FIG. 4 illustrates an example sectional view 400 of a perovskite film between two electrodes in an electrical circuit with a voltage applied. The first electrode 430 may be at a higher voltage than second electrode 440, for example from a battery 450 when coupled with both electrodes, for example by switch 460. The voltage may be a (semi) permanent voltage, as drawn, or it may be in the shape of a signal, such as one or more pulses.
to increase or decrease the resistance of the thin film.

FIG. 5 illustrates an example 500 of a single electrical pulse 510 that may be applied to a perovskite film in an implementation of the technology. Electrical pulse 510 changes the electrical resistance of the perovskite film and changes the effect of electromagnetic shielding. The change in electrical resistance may depend on the amplitude (voltage) and duration of electrical pulse 510.

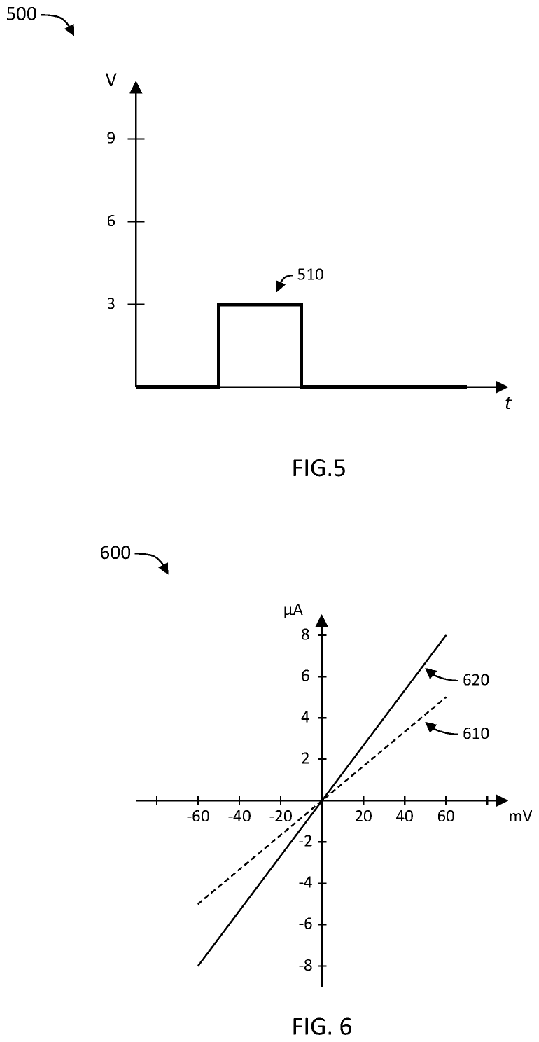

FIG. 6 shows an example I-V graph 600 of a sample film before and after being subject to a +2V pulse. The curve 610 shows the current as a function of the voltage before the pulse is applied, and curve 620 shows the current after the pulse is applied. The resistance, as per Ohm's law, is determined by the differential of the voltage divided by the current, and thus by the inverse of the steepness of the curve. Thus, in this example the resistance of the film is lower after the pulse has been applied.

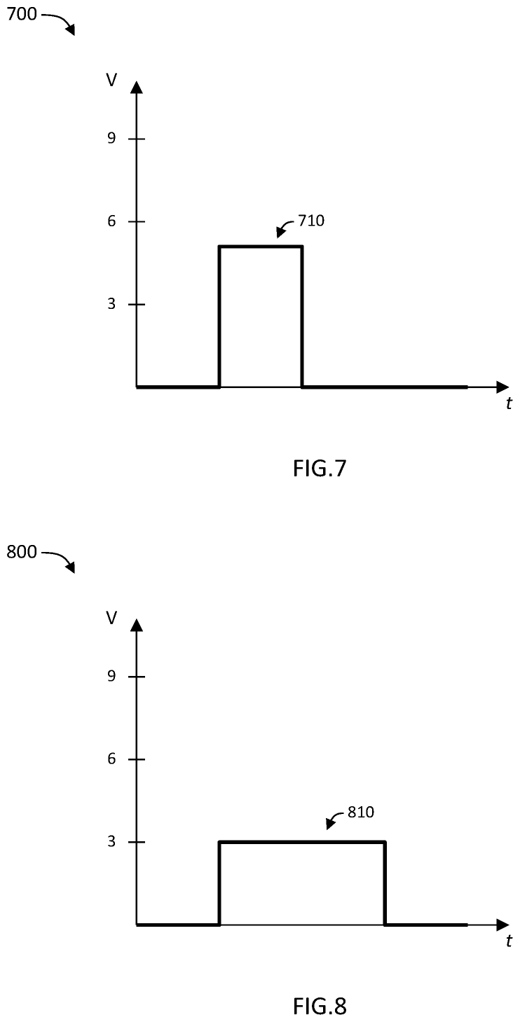

FIG. 7 illustrates an example 700 of a single electrical pulse 710 of a larger amplitude compared to FIG. 6. The amplitude of the pulse may, for example, range between −10V and +10V. The amplitude of the pulse may be changed to alter the total resistance change of the material and the shielding effect. The greater the amplitude, the greater the resistance change and the shielding effect.

FIG. 8 illustrates an example 800 of a single electrical pulse 810 of a different pulse width. The pulse width may range from sub nanoseconds to milliseconds. The greater the pulse width, the greater the resistance change and the shielding effect.

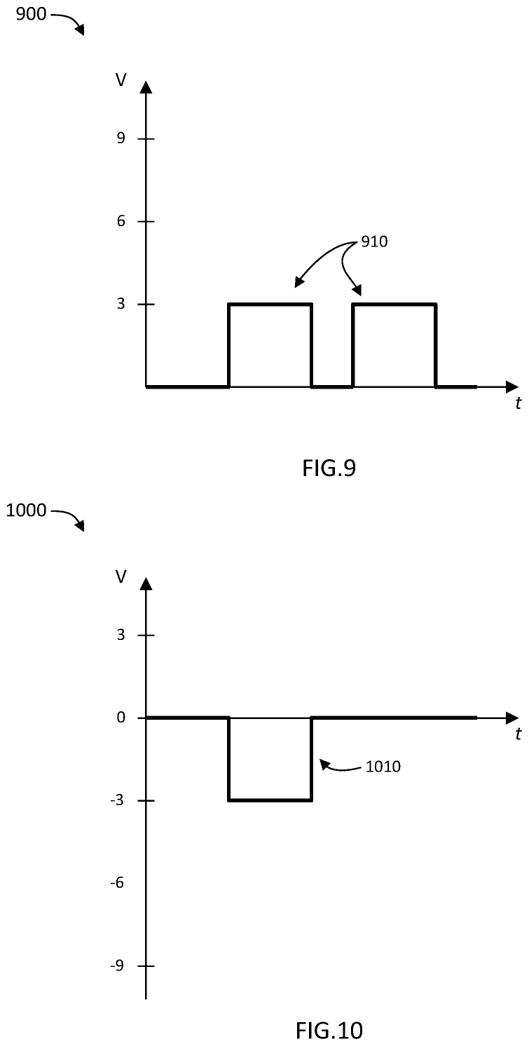

FIG. 9 illustrates an example 900 of multiple electrical pulses 910 that may be applied to the conductive film. The use of multiple pulses alters the total resistance change of the material and the shielding effect. The greater the number of pulses, the greater the resistance change and the shielding effect.

FIG. 10 illustrates an example 1000 of a single negative electrical pulse 1010 that may be applied to a conductive film to reverse the shielding effect.

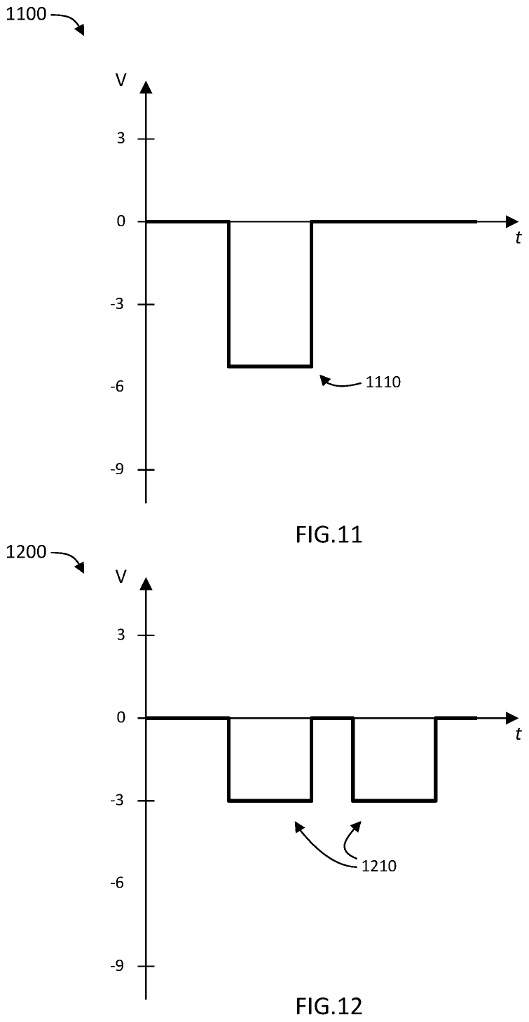

FIG. 11 illustrates an example 1100 of a single negative electrical pulse 1110 of larger amplitude compared to FIG. 10.

FIG. 12 illustrates an example 1200 of multiple negative electrical pulses 1210 that may be applied to a conductive film to reverse the shielding effect.

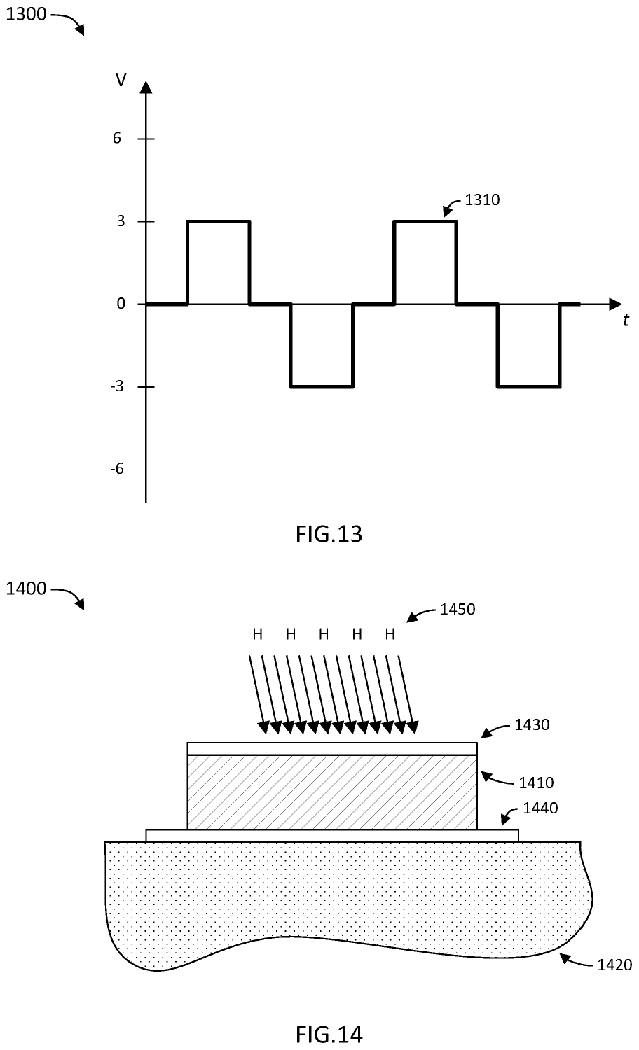

FIG. 13 illustrates an example 1300 of applying repeated positive and negative electrical pulses 1310 to obtain a repeated resistance change.

A change in resistance may be induced by stimuli other than an electrical signal, for example light, a magnetic field, or temperature. In some implementations, this may be accomplished by exposure to chemicals. In some implementations, this chemical is hydrogen. By absorbing hydrogen, the resistance of the perovskite film can be increased greatly.

FIG. 14 illustrates an example 1400 of a perovskite film 1410 between a first electrode 1430 and a second electrode 1440, exposed to hydrogen. Some electrodes including but not limited to platinum and palladium have an affinity for hydrogen. For example, first electrode 1430 may be made of platinum, and second electrode 1440 may be made of gold. Electrode materials may be chosen by their ability to absorb hydrogen.

The absorption of hydrogen and the shielding effect can be changed by heating the film. Absorption of hydrogen greatly increases the resistance and reduces the shielding effect. It is also possible to eliminate the hydrogen from the material by heating the material in air. This greatly reduces the resistance and increases the shielding effect.

The absorption of hydrogen and the shielding effect can be changed by increasing the pressure of the gas. Higher pressure increases the absorption of hydrogen which increases the resistance and reduces the shielding effect.

The transparency of the perovskite film changes with change in its resistance. As the film becomes more resistive, its transparency increases. This provides a visual reference to determine if the shielding effect is in place. With the use of transparent conducting electrodes including but not limited to fluorine tin oxide (FTO) and indium tin oxide (ITO), the entire cage surface may become transparent or opaque with changes in resistance. The opacity of some films like NNO and STO changes with resistance. In a low resistance state, the film is dark and opaque. In a high resistance state the film is clear and transparent. If the films are grown on transparent conducting substrates like FTO or ITO, then the entire shield changes opacity with changes in resistance. So, the shield extends to the visual range of the electromagnetic spectrum. The opacity can provide a visual check of the shielding state of the Faraday cage.

The material film can be made more sensitive to stimuli by doping the film with protons. This also changes the speed of the resistance change. This is accomplished by annealing the film in the presence of hydrogen.

### Considerations

Although the description has been described with respect to particular implementations thereof, these particular implementations are merely illustrative, and not restrictive. The description may reference specific structural implementations and methods and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skills in the art recognize a variety of equivalent variations on the description above.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

It will also be appreciated that one or more of the elements depicted in the drawings/figures can also be implemented in a more separated or integrated manner, or even removed or rendered as inoperable in certain cases, as is useful in accordance with a particular application.

Thus, while particular implementations have been described herein, latitudes of modification, various changes, and substitutions are intended in the foregoing disclosures, and it will be appreciated that in some instances some features of particular implementations will be employed without a corresponding use of other features without departing from the scope and spirit as set forth. Therefore, many modifications may be made to adapt a particular situation or material to the essential scope and spirit.

1. A cage of Faraday, comprising a cavity enveloped by a layer of conductive material whose resistance can be modified by an external stimulus, and wherein the layer of conductive material is configured to receive the external stimulus.

2. The cage of Faraday of claim 1, wherein the layer of conductive material is applied at least partially in a pattern.

3. The cage of Faraday of claim 2, wherein the pattern includes a mesh.

4. The cage of Faraday of claim 2, wherein the pattern includes a stripe.

5. The cage of Faraday of claim 1, wherein the conductive material includes at least one of a perovskite, a metal oxide, an oxide of metallic alloys, or a phase-change memory material.

6. The cage of Faraday of claim 1, wherein a thickness of the conductive material is in a range from one-tenth of a nanometer (0.1 nm) to three centimeters (3 cm).

7. The cage of Faraday of claim 1, wherein the external stimulus is an electrical pulse.

8. The cage of Faraday of claim 7, wherein a voltage of the electrical pulse is between minus ten volts (−10 V) and plus ten volts (+10 V).

9. The cage of Faraday of claim 7, wherein a width of the electrical pulse is from one-tenth of a nanosecond (0.1 ns) to thirty seconds (30 s).

10. The cage of Faraday of claim 7, wherein the electrical pulse is repeated to reach a higher or lower resistance state.

11. The cage of Faraday of claim 10, wherein the higher or lower resistance state provides a different level of shielding to electromagnetic waves.

12. The cage of Faraday of claim 10, wherein the higher or lower resistance state provides a different level of opacity.

13. The cage of Faraday of claim 1, wherein the external stimulus includes at least one of a chemical, hydrogen, an electrolyte, a solid, a liquid, a gas, an operating temperature, an ambient temperature, or a pressure.

14. The cage of Faraday of claim 13, wherein the pressure is different than atmospheric pressure.

15. The cage of Faraday of claim 1, wherein the conductive material is doped with a chemical to increase a speed of a resistance change.

16. The cage of Faraday of claim 15, wherein the conductive material is doped with hydrogen.
